(19) United States
(12) Patent Application Publication
(10) Pub. No.: US 2012/0286370 A1
(43) Pub. Date: Nov. 15, 2012

(54) SEMICONDUCTOR DEVICE AND METHOD FOR MANUFACTURING THE SAME

(75) Inventors: FAN LI, Shanghai (CN); Haiyang Zhang, Shanghai (CN)

(73) Assignee: SEMICONDUCTOR MANUFACTURING INTERNATIONAL (SHANGHAI) CORPORATION, SHANGHAI (CN)

(21) Appl. No.: 13/243,969

(22) Filed: Sep. 23, 2011

(30) Foreign Application Priority Data
May 12, 2011 (CN) 201110121643.8

(51) Int. Cl. H01L 29/78; H01L 21/336

(52) U.S. Cl. 257/408; 438/285; 257/E29.266; 257/E21.409

(57) ABSTRACT

A semiconductor device and method for manufacturing the same are disclosed. The method comprises: forming a gate insulating layer and a gate above a substrate; forming a spacer on both sides of the gate respectively; etching the substrate with the gate and spacers as mask to form indents; respectively forming a dummy sidewall on the side of the spacers opposite to the gate; etching substrate with the gate, spacers and dummy sidewalls as mask to form recesses which are deeper than the indents; removing the dummy sidewalls; and filling SiGe in the indents and recesses to form source/drain extent regions and source/drain regions of the semiconductor device; wherein before the step of filling SiGe, a step of heating the substrate to reflow the substrate material so as to at least change the shape of the side surface of the indent on the side close to the gate is implemented.

### CROSS-REFERENCE TO RELATED APPLICATIONS

This application is based upon and claims the benefit of priority from Chinese Patent Application No. 201110121643.8, filed on May 12, 2011, which is incorporated by reference herein in its entirety.

### BACKGROUND OF THE INVENTION

1. Field of the Invention

This disclosure relates to semiconductor device and method for manufacturing the same, more particularly to a semiconductor device with an embedded silicon germanium (e-SiGe) source/drain structure and a method for manufacturing the same.

2. Description of the Related Art

Improving carrier mobility in channel region can increase the drive current of FETs and enhance device performance. One effective mechanism of increasing carrier mobility is to introduce stress in channel region. Although various channel stress techniques have been proposed, as to pMOSFETs, however, e-SiGe techniques are most effective for stress rising, and have been widely used in modern CMOS techniques to improve pMOSFET performance.

The paper of N. Yasutake, et al. “A High Performance pMOSFET with Two-step Recessed SiGe-S/D Structure for 32 nm node and Beyond” (Solid-State Device Research Conference, 2006, Proceeding of the 36th European, IEEE, pp. 77-80) has disclosed a two-step recessed SiGe source/drain structure, which can dramatically improve the short channel effect and source/drain resistance in pMOSFETs, and achieve more than 80% current increase. It can be known from this paper, SiGe proximity to channel is a dominant parameter to increase channel strain and achieve high performance of pMOSFET, and also is a key parameter to reduce the resistance of source/drain extent (SDE) region. However, as to the existing two-step recessed SiGe source/drain structure as shown in FIG. 1, the distance from the edge of the gate 101 to the SiGe SDE region is defined by the width of the offset spacer 102, which may limit the proximity between the SiGe and the channel.

In view of above issues, it is desirable to provide a method of manufacturing semiconductor device, which can enable the SiGe source/drain structure to be as close as possible to the gate edge, thus achieving a higher performance semiconductor device.

### SUMMARY OF THE INVENTION

One object of this disclosure is to improve the degree of proximity between the SiGe source/drain structure and the gate edge, thus improving performance of the semiconductor device.

According to a first aspect of this disclosure, a method of manufacturing semiconductor device is provided, which may comprise: forming a gate insulating layer and a gate above a substrate; forming a spacer on both sides of the gate respectively; etching the substrate with the gate and the spacers as a mask to form indents; respectively forming a dummy sidewall on the side of the spacers opposite to the gate; etching the substrate with the gate, spacers and dummy sidewalls as a mask to form recesses which are deeper than the indents; removing the dummy sidewalls; and filling SiGe in the indents and the recesses to form source/drain extent regions and source/drain regions of the semiconductor device; wherein before the step of filling the SiGe, a step of heating the substrate to reflow the substrate material so as to at least change the shape of the side surface of the indent on the side close to the gate is implemented.

Preferably, the step of heating the substrate is implemented after the step of forming the indent and before the step of forming the dummy sidewalls.

Preferably, the step of heating the substrate is implemented after the step of removing the dummy sidewalls.

Preferably, the step of heating the substrate is implemented in ambient hydrogen.

Preferably, the substrate is heated at a temperature ranging from 750° C. to 850° C. for 30 secs to 5 mins.

Preferably, the step of filling the SiGe comprises a step of epitaxially growing the SiGe.

Preferably, the SiGe is in-situ doped while epitaxially growing the SiGe.

Preferably, the substrate is halo implanted before the step of forming the spacer and after the step of forming the gate.

Preferably, a rapid low temperature spike annealing is implemented after the step of filling the SiGe.

Preferably, both steps of etching the substrate are implemented by using dry etching processes.

Preferably, the substrate is a silicon substrate.

Preferably, the step of forming the gate insulating layer and the gate comprises forming a layer of silicon dioxide as the gate insulating layer through a thermal oxidation process.

Preferably, the semiconductor device manufactured by the above-mentioned methods is a pMOSFET.

Preferably, the open edge of the indent on the side close to the gate is aligned with the side surface of the gate after the step of heating the substrate.

According to a second aspect of this disclosure, a semiconductor device is provided, which may comprise: a gate insulating layer and a gate above a substrate; spacers on both sides of the gate; a source extent region and a source region integrally formed of SiGe, and a drain extent region and a drain region integrally formed of SiGe in the substrate; wherein the upper ends of edges of the source and drain extent regions on the respective sides close to the gate are located under the spacers.

Preferably, the semiconductor device is a pMOSFET.

Preferably, the substrate is a silicon substrate.

Preferably, the gate insulating layer is a layer of silicon dioxide.

Preferably, the upper ends of edges of the source and drain extent regions on the respective sides close to the gate are respectively aligned with the side surfaces of the gate on the corresponding sides.

One advantage of this disclosure is that, using a two-step recessed SiGe structure enables the semiconductor device size to be further scaled down. The short channel effect also can be greatly improved by optimizing this structure.

Another advantage of this disclosure is that, as compared to the prior art, the source/drain structure of SiGe is enabled to be closer to the channel, thus stress in channel can be increased and semiconductor device performance is improved.

A still another advantage of this disclosure is that, the process of heating to reflow substrate material has excellent process compatibility and low cost. Therefore, extreme proximity between the SiGe structure and gate edge can be realized without a sophisticated etching process. Hence, semiconductor device performance can be greatly improved.

Further features and advantages of this disclosure will become apparent from the following detailed description of exemplary embodiments of this disclosure with reference to the attached drawings.

### BRIEF DESCRIPTION OF THE DRAWINGS

With reference to the drawings, this disclosure will be understood more clearly from the following description. For clarity, thorough the drawings, the relative thickness of each layer and the relative size of each particular region are not illustrated in proportion, in which:

FIG. 1 is a schematic diagram of a semiconductor device having a two-step recessed SiGe source/drain structure in prior art; and

FIGS. 2A-2G are schematical cross-sectional views of the semiconductor device at each stage during its manufacture according to embodiments of this disclosure.

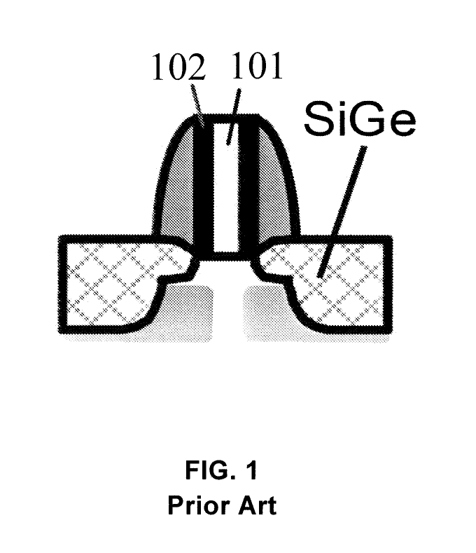

### DESCRIPTION OF THE EMBODIMENTS

Various exemplary embodiments of this disclosure will be described in detail with reference to the drawings.

It has been noted by the present inventors that, in specific ambient conditions (e.g., ambient hydrogen), surface migration of Si atoms may occur at temperatures much lower than the melting point of silicon. In order to minimize the total surface energy, the migration of silicon atoms not only improves surface roughness, but also changes the shape of the Si structure, such as leads to rounded corners. Such effect is similar to that of glass/polymer reflow process. That is, it can be called silicon reflow. Unlike a glass/polymer reflow process, however, this mechanism only depends on the surface migration of atoms, and can retain the crystal structure. Its detailed analysis can be found in the paper of Ming-Chang M. Lee et al. “Thermal Annealing in Hydrogen for 3-D Profile Transformation on Silicon-on-Insulator and Sidewall Roughness Reduction” (J. Microelectromech. Syst., vol. 15, no. 2, pp. 338-343, April, 2006), which is entirely incorporated herein by reference.

This disclosure is proposed based on the above principle.

The following description of at least one exemplary embodiment is merely illustrative in nature and is in no way intended to limit the invention, its application, or uses. Techniques well known in the art can be applied to the parts that are not specifically illustrated or described.

### First Embodiment

In this embodiment, a semiconductor device having a two-step recessed SiGe source/drain structure and its manufacture method are provided, wherein, after initially etching a substrate, the Si substrate is heated so as to lead to Si reflow, which at least changes the shape of the side surface of the indent on the side close to the gate, so that the front end of the indent is closer to the gate edge, or even aligned with the gate edge. The manufacture method will be described in more detail below.

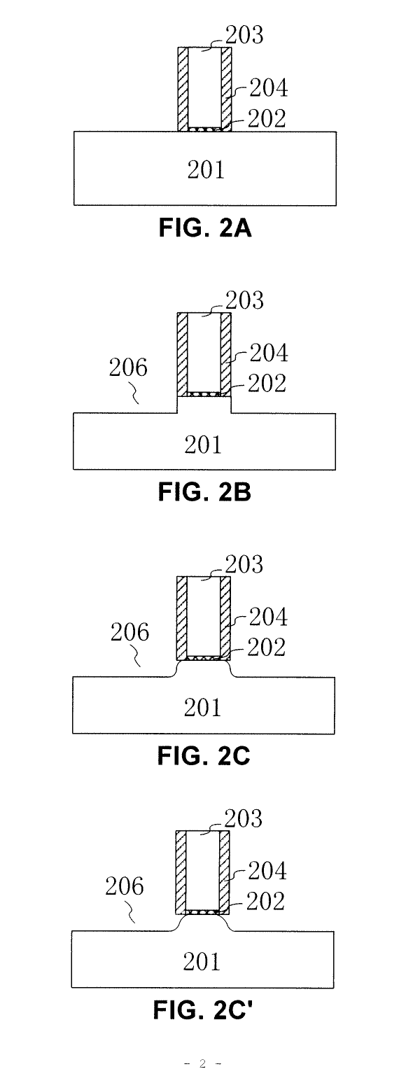

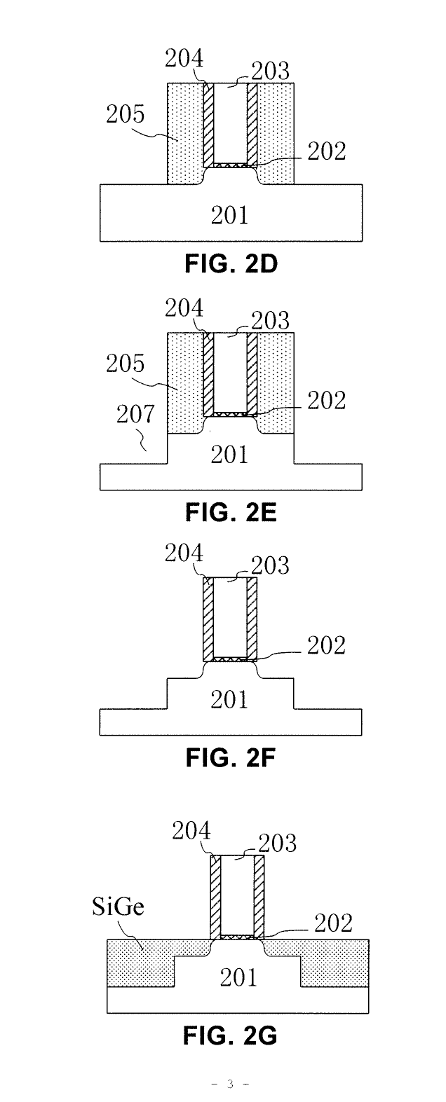

First, as shown in FIG. 2A, a gate insulating layer 202 and a gate 203 are formed above a substrate 201, and then a spacer 204 is formed on both sides of the gate 203 respectively. The spacers 204 may have a thickness of 5 nm to 10 nm. The material of the spacers 204 may be, for example, silicon nitride, silicon oxide or the like. The material of the spacers 204 may be deposited by, for example, chemical vapour deposition (CVD). Optionally, halo ion-implantation may be performed on the substrate before forming the spacers 204 and after forming the gate 203, assisting to control the short channel effect.

Next, as shown in FIG. 2B, the substrate 201 is etched with the gate 203 and the spacers 204 as a mask to form indents 206. The method of etching the substrate may comprise, for example, dry etching, such as, reactive ion etching (RIE) and the like.

Next, as shown in FIG. 2C, the substrate 201 is heated to induce Si reflow so as to at least change the shape of the side surface of the indent 206 on the side close to the gate. The heating step may be implemented in, for example, ambient hydrogen, and the substrate 201 may be heated at a temperature ranging from 750° C. to 850° C. for the duration from 30 secs to 5 mins. During the heating process, Si reflow may occur especially in the regions where a large curvature exists (e.g., corners of the indent obtained through anisotropic etching, such as RIE etching). Therefore, the corners of the indent are rounded, and edges of the indents on the side close to the gate move toward the gate side. As a result, the open edges of the indents on the side close to the gate are located under the spacers 204. In another embodiment, as shown in FIG. 2C′, the temperature, duration and other conditions for the heating process can be controlled so as to align the open edge of the indent on the side close to the gate with the side surface of the gate. In still another embodiment where the gate insulting layer 202 is, for example, a layer of silicon dioxide formed through a thermal oxidation process, since the silicon and the silicon dioxide layer are relatively strongly bonded, and the silicon and the CVD-formed spacers 204 are relatively weakly bonded, Si reflow will stop at the interface between the silicon and the silicon dioxide (i.e., the open edge of the indent on the side close to the gate is aligned with the side surface of the gate) at an appropriate temperature (e.g., 800° C.-850° C.), and no further reflow may occur. Hence, optimal proximity between the two-step recessed SiGe structure and the gate edge may be realized easily and effectively. That is to say, the front end of the SiGe structure on the side close to the gate can be aligned with the gate edge. Note that, in the above embodiment, the gate insulating layer 202 is not limited to the SiO₂ layer formed through thermal oxidation process, and the spacers 204 are not limited to the spacers formed by CVD.

Next, as shown in FIG. 2D, dummy sidewalls 205 which will be removed later are respectively formed on the side of the spacers 204 opposite to the gate. The material of the dummy sidewalls 205 is different from that of the spacers 204. The dummy sidewalls 205 may be made of, such as, silicon nitride, silicon oxide, and the like, and methods such as CVD may be used to deposit the material of the dummy sidewalls 205.

Next, as shown in FIG. 2E, the substrate 201 is etched with the gate 203, the spacers 204 and the dummy sidewalls 205 as a mask to form recesses 207, which are deeper than the above-mentioned indents 206. The substrate may be etched by a dry etching method, such as, reactive ion etching (RIE).

Next, as shown in FIG. 2F, the dummy sidewalls 205 are removed. The method of removing dummy sidewalls 205 may comprise, such as, wet etching methods. For example, hot phosphoric acid may be used in wet etching to remove the dummy sidewalls 205 when the dummy sidewalls 205 are made of silicon nitride, and hydrofluoric acid may be used to remove the dummy sidewalls 205 when the dummy sidewalls 205 are made of silicon oxide.

Next, as shown in FIG. 2G, the indents and recesses are filled with SiGe to form source/drain structures of the semiconductor device, i.e., source/drain extent regions and source/drain regions. Methods of filling the SiGe may comprise, for example, epitaxially growing the SiGe. Optionally, the SiGe may be in situ doped while epitaxially growing the SiGe. An ultra-shallow junction can be realized when the source/drain extent region is formed by in situ doping of SiGe instead of ion-implantation. Optionally, after filling the SiGe, a rapid low temperature spike annealing is implemented to refine the Si/SiGe interface. It is not necessary for the SiGe filled to be flush with the upper surface of the substrate as shown in FIG. 2G, but rather it may be higher than the upper surface of the substrate to form a raised source/drain structure. Preferably, the semiconductor device is a pMOSFET.

### Second Embodiment

The semiconductor device of the second embodiment and its manufacture method are substantially identical to that of the first embodiment, except that, the Si substrate is heated after the second etching of the substrate instead of the first etching of the substrate. Such heating of the substrate induces Si reflow and at least changes the shape of the side surface of the indent on the side close to the gate, such that the front end of the indent is closer to or even aligned with the edge of the gate. In other words, the step of heating the substrate to induce Si reflow is performed after the step of removing the dummy sidewalls 205 and before the step of filling the SiGe in the indents and the recesses.

Just like the first embodiment, the present embodiment enables the upper end of edge of the source/drain extent region on the side close to the gate to be extended beneath the spacer 204 or even aligned with the side surface of the gate. Through enabling the SiGe to be closer to the gate edge, stress in the channel region can be increased, thus improving performance of the semiconductor device. In the present embodiment, the surface roughness of the indents and the recesses can be wholly improved through the Si reflow, and the Si/SiGe interface subsequently formed can be refined also.

Although this disclosure have been described in detail by way of exemplary embodiments, it should be understood by a person skilled in the art that the above exemplary embodiments are only intended to be illustrative but not to limit the scope of this disclosure. It should be understood by a person skilled in the art that the above embodiments can be modified without departing from the scope and spirit of this disclosure. The scope of this disclosure is defined by the attached claims.

What is claimed is:

1. A method of manufacturing a semiconductor device, comprising:
forming a gate insulating layer and a gate above a substrate;
forming a spacer on both sides of the gate respectively;
etching the substrate with the gate and the spacers as a mask to form indents;
respectively forming a dummy sidewall on the side of the spacers opposite to the gate;
etching the substrate with the gate, spacers and dummy sidewalls as a mask to form recesses which are deeper than the indents;
removing the dummy sidewalls; and
filling SiGe in the indents and the recesses to form source/drain extent regions and source/drain regions of the semiconductor device;
wherein before the step of filling the SiGe, a step of heating the substrate to reflow the substrate material so as to at least change the shape of the side surface of the indent on the side close to the gate is implemented.

2. The method according to claim 1, wherein the step of heating the substrate is implemented after the step of forming the indent and before the step of forming the dummy sidewalls.

3. The method according to claim 1, wherein the step of heating the substrate is implemented after the step of removing the dummy sidewalls.

4. The method according to claim 1, wherein the step of heating the substrate is implemented in hydrogen ambient.

5. The method according to claim 4, wherein the substrate is heated at a temperature ranging from 750° C. to 850° C. for 30 secs to 5 mins.

6. The method according to claim 1, wherein the step of filling the SiGe comprises a step of epitaxially growing SiGe.

7. The method according to claim 6, wherein the SiGe is in-situ doped while epitaxially growing the SiGe.

8. The method according to claim 1, wherein the substrate is halo implanted before the step of forming the spacer and after the step of forming the gate.

9. The method according to claim 1, wherein a rapid low temperature spike annealing is implemented after the step of filling the SiGe.

10. The method according to claim 1, wherein both steps of etching the substrate are implemented by using dry etching processes.

11. The method according to claim 1, wherein the substrate is a silicon substrate.

12. The method according to claim 11, wherein the step of forming the gate insulating layer and the gate comprises forming a layer of silicon dioxide as the gate insulating layer through a thermal oxidation process.

13. The method according to claim 1, wherein the semiconductor device is a pMOSFET.

14. The method according to claim 1, wherein the open edge of the indent on the side close to the gate is aligned with the side surface of the gate after the step of heating the substrate.

15. A semiconductor device, comprising:
a gate insulating layer and a gate above a substrate;
spacers on both sides of the gate;
a source extent region and a source region integrally formed of SiGe, and a drain extent region and a drain region integrally formed of SiGe in the substrate;
wherein the upper ends of edges of the source and drain extent regions on the respective sides close to the gate are located under the spacers.

16. The semiconductor device according to claim 15, wherein the semiconductor device is a pMOSFET.

17. The semiconductor device according to claim 15, wherein the substrate is a silicon substrate.

18. The semiconductor device according to claim 17, wherein the gate insulating layer is a layer of silicon dioxide.

19. The semiconductor device according to claim 15, wherein the upper ends of edges of the source and drain extent regions on the respective sides close to the gate are respectively aligned with the side surfaces of the gate on the corresponding sides.
